(19) United States
(12) Patent Application Publication
(10) Pub. No.: US 2008/0157305 A1
(43) Pub. Date: Jul. 3, 2008

(54) CHIP PACKAGE STRUCTURE

(75) Inventor: Guo-Cheng Liao, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/781,420

(22) Filed: Jul. 23, 2007

(30) Foreign Application Priority Data
Jan. 3, 2007 (TW) 96100214

(51) Int. Cl. H01L 23/495

(52) U.S. Cl. 257/676; 257/E23.031

(57) ABSTRACT

A chip package structure including a circuit board, a solder mask, and a chip package is provided. The circuit board has at least one contact on its surface. The solder mask covers the circuit board and has at least one first opening for exposing the contact. The chip package is disposed on the circuit board, and includes a chip and a leadframe, which has at least one lead that is electrically connected to the chip. The lead has an insertion portion that corresponds to the contact and inserts into the first opening. A solder bump is filled into the first opening and fastened to the insertion portion, thereby the connection between the lead and the contact of the chip package structure is secured.

### CROSS-REFERENCE TO RELATED APPLICATION

This application claims the priority benefit of Taiwan application serial no. 96100214, filed on Jan. 3, 2007. All disclosure of the Taiwan application is incorporated herein by reference.

### BACKGROUND OF THE INVENTION

1. Field of the Invention

The present invention relates to a chip package structure, and more particularly to a package structure using a leadframe to support a chip.

2. Description of Related Art

For the fabrication of an integrated circuit (IC), such as wafer manufacturing, IC layout, and wafer sawing are performed for fabricating multiple chips (or dice). After IC layout on the wafer is finished, the chips formed by wafer sawing are externally electrically connected to a carrier. The carrier is, for example, a leadframe or a substrate, and the chip is electrically connected to the carrier by means of wire bonding or flip chip bonding. If the chip is electrically connected to the carrier by means of wire bonding, it proceeds to a process of filling a molding compound, thereby forming a chip package.

FIG. 1 is a sectional view of a conventional chip package structure. Referring to FIG. 1, the chip package structure 100 includes a substrate 110 and a chip package 120. The chip package 120 includes a chip 122 and a leadframe 124. A pad 126 on the chip 122 is electrically connected to a lead 124a of the leadframe 124 through a lead 128, and is disposed on a surface of the substrate 110 through the lead 124a extended out of a molding compound 130.

The substrate 110 has a contact 114 at one side thereof corresponding to the lead 124a, and the contact 114 is exposed by an opening 112a of a solder mask 112, and is electrically connected to the lead 124a through a solder 140 or a solder paste coated in the opening 112a. With the surface mounting technology (SMT) described above, the chip package 120 is effectively assembled on the substrate 110, thus saving process time.

However, poor coplanarity of the lead 124a, poor planarity of the substrate 110, or influence of thermal stress would result in the deformation of the chip package structure 100. Particularly, a high temperature generated by reflowing solder may make the substrate 110 to generate warpage, thus affecting the assembly reliability of the chip package structure 100. Further, since the lead 124a of the chip package structure 100 only has a contact surface with the solder bump 140 at the opening 112a, a poor fixing of the solder bump 140 to the lead 124a is easily caused, thereby reducing the reliability of the chip package structure 100.

### SUMMARY OF THE INVENTION

The present invention is directed to providing a chip package structure, for securing the connection between a lead and a contact through changing the structure of the lead.

In order to solve the above problem, a chip package structure including a circuit board, a solder mask, and a chip package is provided. The circuit board has at least one contact on its surface. The solder mask covers the circuit board, and has at least one first opening for exposing the contact. Moreover, the chip package is disposed on the circuit board, and the chip package includes a chip and a leadframe. The leadframe has at least one lead electrically connected to the chip, and the lead has an insertion portion that corresponds to the contact and inserts in the first opening.

In an embodiment of the present invention, the chip package structure further includes a solder bump filled in the first opening, and electrically connected to the insertion portion and the contact.

In an embodiment of the present invention, the solder bump is formed by printing a solder paste on the first opening.

In an embodiment of the present invention, the solder bump includes a fixed portion correspondingly protruding from the insertion portion, such that the solder bump encapsulates the insertion portion.

In an embodiment of the present invention, the insertion portion of the lead includes at least one second opening, and the solder bump protrudes from the insertion portion through the second opening to form a protruding portion (or a fixed portion), such that the solder bump forms a rivet portion at the second opening.

In an embodiment of the present invention, the insertion portion further includes a third opening, and the lead includes a connection portion correspondingly between the second opening and the third opening.

In an embodiment of the present invention, the second opening is semicircular shaped or semi-elliptical shaped.

In an embodiment of the present invention, the third opening is semicircular shaped or semi-elliptical shaped.

In an embodiment of the present invention, the connection portion is rectangular shaped.

In an embodiment of the present invention, the insertion portion the insertion portion includes a plurality of openings, and the lead includes at least two connection portions correspondingly between the openings.

In an embodiment of the present invention, the openings are sector-shaped.

In an embodiment of the present invention, at least two connection portions are cross-shaped, Y-shaped or X-shaped.

In an embodiment of the present invention, the insertion portion includes a recess formed by punching on a surface of the lead.

In an embodiment of the present invention, the chip is electrically connected to an end of the lead by means of wire bonding.

In an embodiment of the present invention, the chip is electrically connected to an end of the lead by means of flip chip bonding.

In the present invention, an insertion portion is disposed at one end of the lead in contact with the contact, and the insertion portion inserts in the first opening, such that the contact area of the solder bump and the lead is increased, and the solder bump encapsulates the insertion portion to form a better fixing effect of the solder bump to the lead, thereby avoiding the connection between the lead and the contact from breaking off due to the deformation of the chip package structure.

In order to make the aforementioned and other objects, features and advantages of the present invention comprehensible, preferred embodiments accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a sectional view of a conventional chip package structure.

FIG. 2 is a sectional view of a chip package structure according to a first embodiment of the present invention.

FIG. 3 is a sectional view of a chip package structure according to another embodiment of the present invention.

FIG. 4A is a top view of a chip package structure according to a second embodiment of the present invention.

FIG. 4B is a side view of the insertion portion in FIG. 4A.

FIG. 5A is a top view of the insertion portion according to another embodiment of the present invention.

FIG. 5B is a side view of the insertion portion in FIG. 5A.

FIG. 6A is a top view of the insertion portion according to a third embodiment of the present invention.

FIG. 6B is a side view of the insertion portion in FIG. 6A.

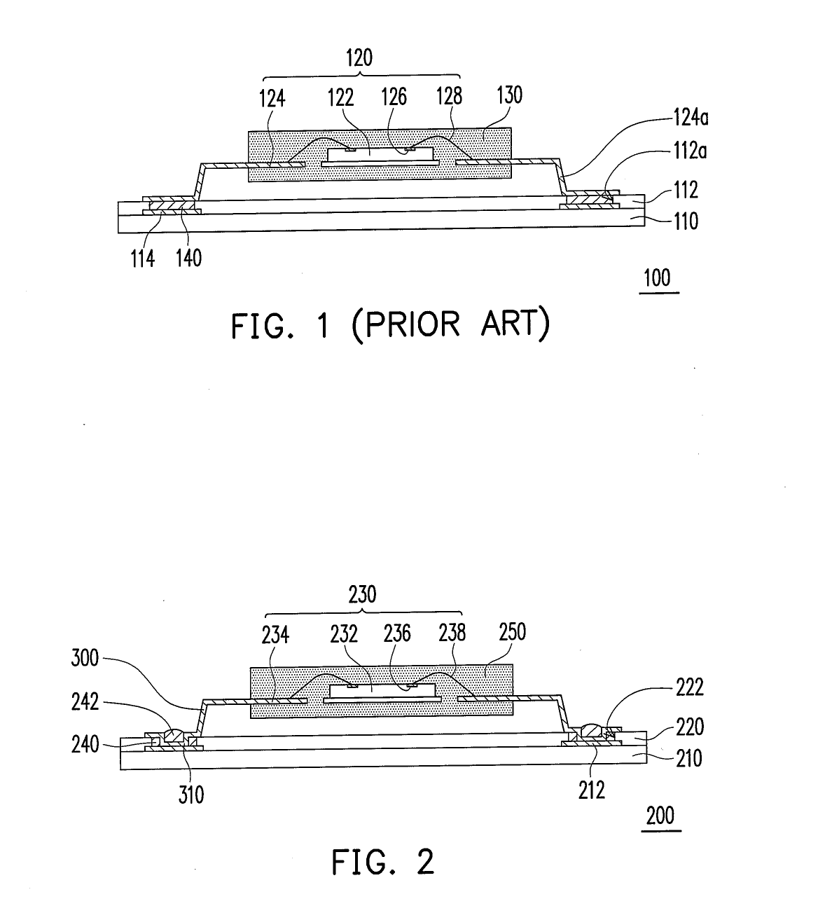

### DESCRIPTION OF EMBODIMENTS

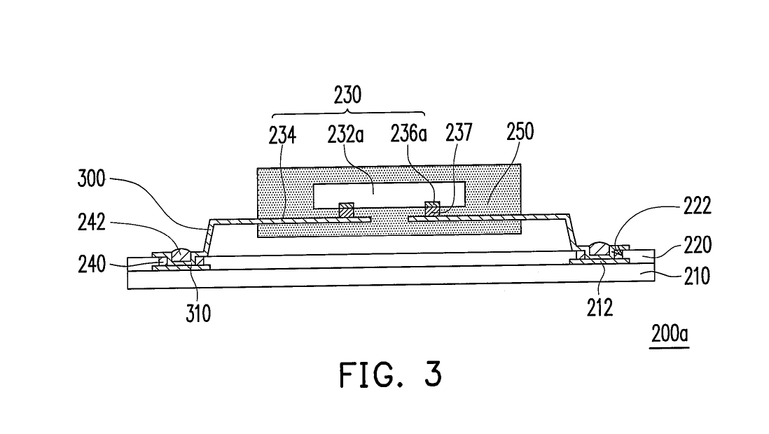

FIG. 2 is a sectional view of a chip package structure according to a first embodiment of the present invention. It should be noted that in the following description, only a circuit board having two contacts and two first openings is illustrated, but the present invention is not limited to this, and those skilled in the art can also only dispose one contact and one first opening on the circuit board, or dispose more than two contacts and first openings.

Referring to FIG. 2, the chip package structure 200 includes a circuit board 210, a solder mask 220, and a chip package 230. The solder mask 220 covers the circuit board 210, and the solder mask 220 is formed on the circuit board 210 by means of screen printing, spraying, or coating. The solder mask 220 has a first opening 222 for exposing a contact 212 on the circuit board 210.

The chip package 230 includes a chip 232 and a leadframe 234, and the chip 232 is electrically connected to a lead 300 of the leadframe 234. In detail, a pad 236 on the chip 232 is electrically connected to the lead 300 through a wire 238 by means of wire bonding. The chip 232 can also be electrically connected to the lead 300 by other means. For example, a flip chip package structure 200a is shown in FIG. 3, a gold bump or solder bump 237 is fabricated on the chip 232a and/or the lead 300, and the chip 232a is attached to the lead 300 by means of flip chip, such that the chip 232a is electrically connected to the lead 300. Then, after the chip 232a is assembled, a molding compound 250 is further used to encapsulate the chip 232a and the bump 237. The lead 300 extends out of the molding compound 250, and is bent into a predetermined shape to support the chip package 230 on the circuit board 210. The bent shape of the lead 300 is not limited, and can be formed with a structure of an outer L-shape, an inner L-shape, or a J-shape.

It should be noted that the lead 300 has an insertion portion 310 formed by, for example, performing punching or hot pressing on a surface of the lead 300 such that a portion of the lead 300 inserts in the first opening 222 to form the insertion portion 310. In the chip package structure 200 of this embodiment, a solder bump 240 is used to electrically connect the lead 300 to the contact 212 and fix the lead 300. In particular, the solder bump 240 is, for example, formed in the first opening 222 by solder paste printing, and the solder paste is reflowed to be connected between the insertion portion 310 and the contact 212. In order to further fix the lead 300, during the reflow of the solder bump 240, a portion of the solder bump 240 is protruded, so as to encapsulate the insertion portion 310 to form a protruding portion 242. Accordingly, the solder bump 240 encapsulates the insertion portion 310 to enhance the fixing effect of the solder bump 240 to the lead 300.

The lead 300 of the chip package structure 200 according to the present invention has an insertion portion 310, and the insertion portion 310 inserts in the first opening 222. Therefore, the solder bump 240 encapsulates the insertion portion 310, which not only increases the contact surface of the solder bump 240 and the insertion portion 310, provides preferable electric characteristic for the connection between the contact 212 and the lead 300, but also allows the solder bump 240 to fix the insertion portion 310 from the above of the insertion portion 310, thereby securing the connection between the contact 212 and the lead 300.

### The Second Embodiment

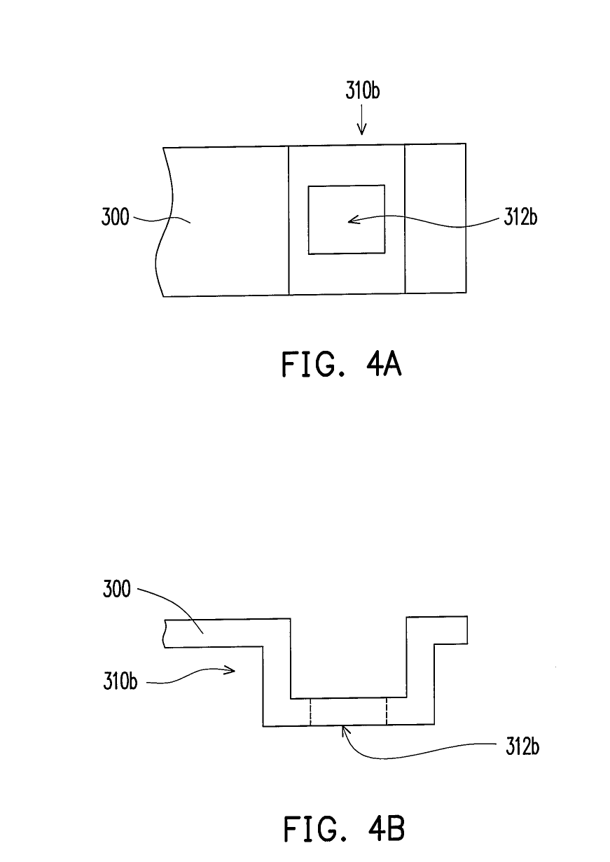

FIG. 4A is a top view of an insertion portion according to a second embodiment of the present invention, and FIG. 4B is a side view of the insertion portion in FIG. 4A. In the second embodiment and the first embodiment, same or like reference numerals represent same or like devices. The second embodiment is similar to the first embodiment, and will not be described hereinafter except the differences between the two embodiments.

Referring to FIG. 4A and FIG. 4B, the second embodiment differs from the first embodiment in terms that an insertion portion 310b further includes a second opening 312b. The second opening 312b is formed, for example, by means of etching, or formed at the same time when the insertion portion 310b is formed by punching. The second opening 312b is triangular shaped, semicircular shaped, or semi-elliptical shaped. The solder bump 240 protrudes from the insertion portion 310b through the second opening 312b to form a protruding portion 242, thereby increasing the contact area of the solder bump 240 and the insertion portion 310b, such that the solder bump 240 forms a rivet portion at the second opening 312b to securing the connection between the contact 212 and the lead 300.

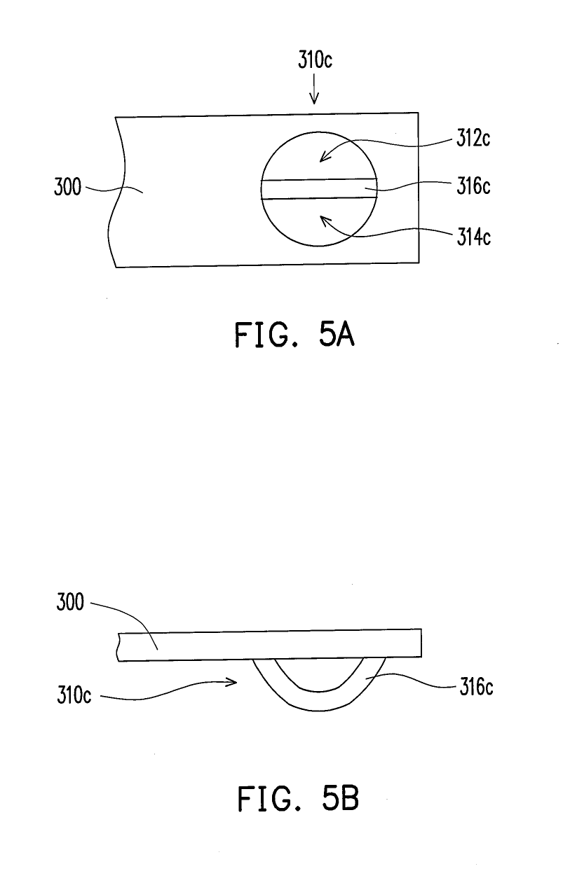

FIG. 5A is a top view of the insertion portion according to still another embodiment of the present invention, and FIG. 5B is a side view of the insertion portion in FIG. 5A. Referring to FIG. 5A and FIG. 5B, in this embodiment, besides the recessed cup structure as shown in FIG. 4B, the insertion portion can also be an arc structure shown in FIG. 5B. For example, a second hollowed-out opening 312c and a third hollowed-out opening 314c are first formed around the insertion portion 310c, and the lead 300 only preserves a connection portion 316c to be formed between the second opening 312c and the third opening 314c, and finally the connection portion 316c is punched into the desired recess structure.

The shape and fabrication method of the second opening 312c and the third opening 314c can refer to the second opening 312b, which will not be described herein. Moreover, the connection portion 316c can also be other shapes. For example, the second opening and the third opening are triangular shaped, and the connection portion is trapezoidal shaped. The shapes of the second opening and the third opening can be different, for example, the second opening is square shaped, and the third opening is semicircular shaped.

In this embodiment, the second opening and the third opening are illustrated as a example; however, the insertion portion can have more than two openings, which is illustrated hereinafter in another embodiment.

### The Third Embodiment

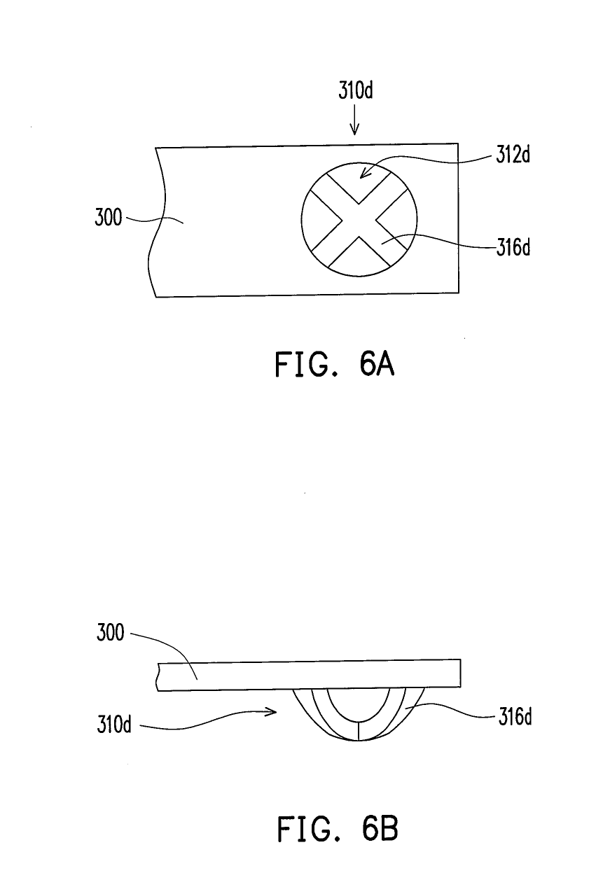

FIG. 6A is a top view of the insertion portion according to a third embodiment of the present invention, and FIG. 6B is a side view of the insertion portion in FIG. 6A. In the third embodiment and the first embodiment, same or like reference numerals represent same or like devices. The third embodiment is similar to the second embodiment, and will not be described hereinafter except the differences between the two embodiments.

Referring to FIG. 6A and FIG. 6B, in this embodiment, a plurality of hollowed-out openings 312d, for example, sector-shaped openings, are formed around the insertion portion 310d, and the lead 300 only preserves a plurality of cross-connected connection portions 316d between the openings 312d, and finally the connection portions 316d are punched to form desired recess structure. The quantity of the openings, the shape of the openings, and the shape of the connection portions are not limited in this embodiment, and the shapes of the openings can be varied. For example, the insertion portion may have two sector openings and a triangular opening, such that the connection portion looks like Y-shaped. The connection portion can also be in other shapes, such as cross-shape, and triangular shape, and other shapes of the opening can refer to the second opening and the third opening in the second embodiment, which will not be described herein again.

In view of the above, the present invention at least has the following advantages:

(1). In the chip package structure according to the present invention, the lead has an insertion portion, such that the solder bump encapsulates the insertion portion. Therefore, the contact area of the solder bump and the lead is increased, and a better fixing effect of the solder bump to the lead is achieved, thereby securing the connection between the lead and the contact, and improving the reliability of the product.

(2). The insertion portion according to the present invention further includes one or more openings, such that the solder bump protrudes from the openings, and forms a rivet portion at the openings. Therefore, the effect of fixing the solder bump to the lead is further enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package structure, comprising:
a circuit board, having at least one contact on its surface;
a solder mask, covering the circuit board, and having at least one first opening for exposing the contact; and
a chip package, disposed on the circuit board, and comprising a chip and a leadframe, wherein the leadframe comprises at least one lead electrically connected to the chip, and the lead comprises an insertion portion that corresponds to the contact, and inserts in the first opening.

2. The chip package structure as claimed in claim 1, further comprising a solder bump filled in the first opening, and electrically connected to the insertion portion and the contact.

3. The chip package structure as claimed in claim 2, wherein the solder bump is formed by printing a solder paste on the first opening.

4. The chip package structure as claimed in claim 2, wherein the solder bump comprises a fixed portion correspondingly protruding from the insertion portion.

5. The chip package structure as claimed in claim 1, wherein the insertion portion of the lead comprises at least one second opening.

6. The chip package structure as claimed in claim 5, wherein the insertion portion further comprises a third opening, and the lead comprises a connection portion correspondingly between the second opening and the third opening.

7. The chip package structure as claimed in claim 5, wherein the second opening is semicircular shaped or semi-elliptical shaped.

8. The chip package structure as claimed in claim 6, wherein the third opening is semicircular shaped or semi-elliptical shaped.

9. The chip package structure as claimed in claim 6, wherein the connection portion is rectangular shaped.

10. The chip package structure as claimed in claim 1, wherein the insertion portion comprises a plurality of openings, and the lead comprises at least two connection portions correspondingly between the openings.

11. The chip package structure as claimed in claim 10, wherein the openings are sector-shaped.

12. The chip package structure as claimed in claim 10, wherein the at least two connection portions are cross-shaped, Y-shaped or X-shaped.

13. The chip package structure as claimed in claim 1, wherein the insertion portion comprises a recess formed by punching on a surface of the lead.

14. The chip package structure as claimed in claim 1, wherein the chip is electrically connected to an end of the lead by means of wire bonding.

15. The chip package structure as claimed in claim 1, wherein the chip is electrically connected to an end of the lead by means of flip chip bonding.
